(19) United States
(12) Patent Application Publication
(10) Pub. No.: US 2018/0366579 A1
(43) Pub. Date: Dec. 20, 2018

(54) LATERALLY DIFFUSED FIELD EFFECT TRANSISTOR IN SOI CONFIGURATION

(71) Applicant: GLOBALFOUNDRIES Inc., Grand Cayman (KY)

(72) Inventors: Ran Yan, Dresden (DE); Ming-Cheng Chang, Dresden (DE); Thomas Merbeth, Dresden (DE)

(21) Appl. No.: 15/622,591

(22) Filed: Jun. 14, 2017

(51) Int. Cl. H01L 29/78; H01L 29/10; H01L 29/66; H01L 29/423; H01L 27/12; H01L 29/08; H01L 21/84

(52) U.S. Cl. CPC H01L 29/7824; H01L 29/1045; H01L 29/66681; H01L 29/42368; H01L 29/0882; H01L 27/1203; H01L 29/0865; H01L 21/84; H01L 29/1095

(57) ABSTRACT

A high voltage transistor may be formed on the basis of CMOS techniques for forming sophisticated SOI devices, wherein a fully depleted channel portion may result in low on-resistance and high breakdown voltage. Thus, an LDMOS-type transistor may be formed on the basis of a fully depleted drift region, thereby providing a high degree of scalability and process compatibility with sophisticated CMOS techniques.

### BACKGROUND

### 1. Field of the Disclosure

Generally, the present disclosure relates to semiconductor devices and manufacturing techniques in which transistor elements are to be formed on the basis of a semiconductor- or silicon-on-insulator (SOI) architecture, while additionally implementing mechanisms for extending transistor characteristics, in particular, in view of operating voltage and/or on-resistance.

### 2. Description of the Related Art

Significant progress has been made in the field of semiconductor devices, including active circuit elements, such as transistors in the form of field effect transistors, bipolar transistors and the like. In recent developments, critical dimensions of the transistor elements have reached 30 nm and even less in sophisticated planar device architectures, while even further reduced critical dimensions may be implemented in three-dimensional transistor architectures, such as FinFETs and the like. Although reduction of the critical dimensions is basically driven by a demand for ever-increasing transistor performance at low power consumption, it appears that these demands may frequently result in certain compromises that have to be made, since the reduction of critical dimensions to achieve high integration density and, thus, relatively low cost, is often associated with significant influences on transistor performance.

For example, upon steadily reducing the critical dimensions of sophisticated CMOS transistor elements, extremely high integration density may be achieved, for instance, by implementing several hundred millions of individual transistor elements into a single integrated circuit chip, thereby forming highly complex circuitry or even entire systems on a single chip. Typically, certain countermeasures may have to be developed so as to address various side effects accompanying the reduction of the critical dimensions, such as the gate length of sophisticated field effect transistors. Some of these adverse effects of the continuous reduction of the gate length of sophisticated field effect transistors are associated with the capacitive coupling between the conductive channel forming below the gate electrode structure, the parasitic capacitance of the remaining transistor body with respect to the gate electrode structure, thereby increasing static and dynamic leakage currents into and through a very thin gate dielectric material, and the like. For example, capacitive coupling of the gate electrode structure to the channel region has required a continuous reduction of the physical thickness of the gate dielectric material, which, on the other hand, may significantly contribute to increased leakage currents into and through the thin gate dielectric material. Therefore, sophisticated material systems and manufacturing techniques have been developed in order to introduce high-k dielectric materials into the gate dielectric material, thereby obtaining a physical thickness appropriate for maintaining leakage currents at an acceptable level, while the resulting electrical thickness or oxide equivalent thickness may be further reduced.

In an attempt to further enhance overall controllability of the channel region of highly-scaled field effect transistors, in recent developments, the problem of unavoidable dopant fluctuations in channel regions of a length of 30 nm and significantly less may be addressed by further reducing the dopant concentration in the channel region, thereby also reducing scattering events, thus, increasing overall speed of charge carriers in the channel region and also contributing to superior transistor performance. Furthermore, it has been recognized that a fully depleted transistor body region, i.e., at zero voltage applied to electrode structure, substantially no mobile charge carriers are present within the entire channel region and body region of the transistor, also superior transistor performance, in particular, in view of overall channel controllability, may be achieved. A fully depleted transistor configuration may be obtained by using a very thin semiconductor material, such as a silicon material, a silicon/germanium material and the like, so that, in combination with no, or a very low, dopant concentration in this very thin semiconductor region, the desired fully depleted state may be obtained. Due to the substantially intrinsic or lowly-doped state of the semiconductor material, appropriate mechanisms for adjusting the threshold voltage of respective transistors have been developed, since conventional threshold voltage adjusting mechanisms based on highly doped polysilicon are no longer effective. Therefore, implementation of metal species in sophisticated high-k metal gate electrode structures has been proposed and these approaches may also require sophisticated techniques for adjusting the desired threshold voltage by incorporating appropriate metal species and the like.

In view of these developments and in addition to some advantages associated with an SOI architecture, i.e., an architecture in which a buried insulating material is formed below the respective active semiconductor material, sophisticated circuit designs have been developed on the basis of the SOI architecture, thereby also providing an additional mechanism for adjusting the threshold voltage, since the semiconductor region below the buried insulating material may be appropriately doped so as to influence the conductivity of the channel region in the semiconductor material positioned above the buried insulating layer. Consequently, in view of many advantages offered by the SOI technique, highly complex integrated circuits have been designed so that small signal capabilities of modern integrated circuits are significantly enhanced, while, at the same time, the reduced overall dimensions contribute to superior speed of critical signal paths, also resulting in reduced power consumption.

When implementing more and more functions into a single integrated circuit, however, not only small signal capabilities are of great importance, but also high voltages and/or high currents may have to be taken into consideration, for instance, when implementing amplifiers and the like. For example, the capability of wireless communication between various devices is widely used in many technical fields, thereby requiring output amplifiers of respective transmitter components, which may have to be operated on the basis of elevated voltages compared to low power, small signal transistor elements. Although transistor elements operating on the basis of increased supply voltages and higher drive currents may be formed on the basis of specific semiconductor compounds, such as gallium arsenide and the like, it turns out that such approaches may be associated with a significant increase in overall manufacturing costs and may, therefore, represent approaches less than desirable for many technical applications. Therefore, transistor architectures have been developed that provide a high degree of compatibility with conventional CMOS techniques, while, at the same time, allowing the operation at elevated supply voltages and/or increased drive currents. To this end, transistor architectures have been developed in which so-called “drift regions” are implemented between the drain and source regions in order to provide an increased “length” for the voltage drop, in particular, at the drain side of the transistor. That is, laterally extended, appropriately doped regions, i.e., the drift regions, have been implemented in order to increase the breakdown voltage of a corresponding transistor, while also an appropriate thickness of the gate dielectric material has to be selected. Since a moderately reduced on-resistance is typically desired, however, a significant increase of the length of a corresponding drift region, typically having a moderately high yet reduced dopant concentration with respect to the actual drain region, may contribute to an increased overall resistance between the source and the drain region. Consequently, significant efforts have been made to provide an appropriate laterally diffused MOS (LDMOS) transistor, for instance, by appropriately shaping the corresponding drift region, including blocking regions, with inverse doping and the like, in order to obtain a desired compromise between increased breakdown voltage and reduced on-resistance. Although very promising approaches have been undertaken, it appears, however, that presently available LDMOS transistors may still contribute to increased on-resistance and/or reduced breakdown voltage and/or may lack compatibility with sophisticated CMOS techniques, thereby rendering any such approaches less than desirable for implementation in sophisticated SOI architectures as described above.

In view of the situation described above, the present disclosure, therefore, relates to semiconductor devices and manufacturing techniques in which a laterally diffused MOS (LDMOS) transistor may be formed on the basis of sophisticated CMOS techniques, while avoiding, or at least reducing, the effects of one or more of the problems identified above.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is based on the finding that the concept of implementing a substantially fully depleted drift region in a laterally diffused field effect transistor may achieve a desired voltage drop in a substantially linear manner along the length of the drift region. At the same time, the fully depleted configuration and, thus, a correspondingly reduced dopant concentration in the drift region may contribute to increased charge carrier speed, for instance, due to a significant reduction of the probability of scattering events, thereby contributing to superior overall conductivity and, thus, reduced on-resistance. In some illustrative embodiments, the concept of a fully depleted drift region may be implemented on the basis of an SOI architecture, thereby contributing to a high degree of compatibility with sophisticated small signal CMOS techniques based on an SOI architecture in combination with fully depleted low power transistors. The inventive concept is, thus, advantageously applicable to circuit designs, in which, at least in certain circuit areas, devices have to be operated on the basis of a relatively high supply voltage, since, due to the substantially depleted drift region, the electrical field may be linearly reduced along the length of the substantially depleted drift region, thereby also providing a mechanism for adjusting the required breakdown voltage of the field effect transistor under consideration by adapting the length of the drift region to the required operating voltage. Furthermore, the inventive concepts are well-suited for radio frequency (RF) applications, such as the output stage of a power amplifier in RF transmitters, since, due to the characteristics of the substantially fully depleted drift region, a very low on-resistance may be achieved.

In one illustrative embodiment disclosed herein, a semiconductor device includes a laterally diffused field effect transistor. The laterally diffused field effect transistor includes a first channel portion of a channel region having a first doping of a first conductivity type. The laterally diffused field effect transistor further includes a second channel portion of the channel region having a second doping of a second conductivity type that is inverse to the first conductivity type, wherein the second channel portion has a thickness of 15 nm or less. Moreover, the field effect transistor includes a continuous gate electrode structure having a first gate portion formed on the first channel portion and having a second gate portion formed on the second channel portion, wherein the first and second gate portions comprise a gate dielectric material of different thickness, respectively. Furthermore, the laterally diffused field effect transistor includes a drain region formed so as to connect to the second channel portion and a source region formed so as to connect to the first channel portion.

A further illustrative embodiment disclosed herein relates to a method. The method includes forming a channel region of the field effect transistor of a semiconductor device in a semiconductor layer of a thickness of 15 nm or less, wherein the channel region has a first channel portion doped with a dopant species of a first conductivity type and a second channel portion doped with a dopant species of a second conductivity type. The method further includes forming a gate electrode structure on the channel region.

According to a still further illustrative embodiment, a method is provided relating to forming a field effect transistor. The method includes introducing a first dopant species into a first portion of a semiconductor layer of a semiconductor device so as to form a first channel portion, wherein the semiconductor layer is formed on a buried insulating layer. The method further includes introducing a second dopant species into a second portion of the semiconductor layer so as to form a second channel portion, wherein the first and second dopant species induce different conductivity types in the first and second channel portions, respectively. Furthermore, the method includes forming a gate electrode structure above the semiconductor layer so as to form a first gate portion on the first channel portion and a second gate portion on the second channel portion. Additionally, the method includes forming drain and source regions laterally adjacent to the gate electrode structure.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a semiconductor device, including various device regions, at least one of which may receive a field effect transistor of increased breakdown voltage and low on-resistance in a very early phase of the overall manufacturing process;

FIG. 2 schematically illustrates a cross-sectional view of the semiconductor device of FIG. 1, wherein a channel region may be doped so as to form a first channel portion having a specific type of conductivity, according to illustrative embodiments;

FIG. 3 schematically illustrates a cross-sectional view of the semiconductor device in a further manufacturing stage, in which a second channel portion is formed so as to have an inverse doping with respect to the first channel portion;

FIG. 4 schematically illustrates a cross-sectional view of the semiconductor device in a further advanced manufacturing stage, in which a gate dielectric material of appropriate thickness may be formed in accordance with illustrative embodiments;

FIG. 5 schematically illustrates a cross-sectional view of the semiconductor device during a manufacturing phase in which a portion of the thick dielectric material is removed;

FIG. 6 schematically illustrates a cross-sectional view of the semiconductor device in a manufacturing stage, in which a sophisticated gate dielectric material on the basis of a high-k dielectric material may be formed on an exposed portion of the field effect transistor and possibly in other low-power transistor elements;

FIG. 7 schematically illustrates a cross-sectional view of the semiconductor device in a further advanced manufacturing stage, in which gate electrode structures are formed on the channel regions of the field effect transistor and possibly on the channel regions of low power transistor elements;

FIG. 8 schematically illustrates a cross-sectional view of the semiconductor device, in which the gate electrode structures are illustrated in a further advanced stage;

FIG. 9 schematically illustrates a cross-sectional view of the semiconductor device in a stage wherein raised drain and source regions may be formed in accordance with illustrative embodiments;

FIG. 10 schematically illustrates a cross-sectional view of the semiconductor device with additional sidewall spacers used to remove a dielectric cap of the gate electrode structures according to illustrative embodiments;

FIG. 11 schematically illustrates the semiconductor device in a further advanced manufacturing stage, in which the dielectric cap material has been removed; and

FIG. 12 schematically illustrates the semiconductor device in an advanced manufacturing stage, in which highly conductive metal semiconductor compound materials may be provided in the drain and source regions and the gate electrode structures of the field effect transistor and any low power transistor elements.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure is based on the concept that field effect transistors of increased breakdown voltage and/or reduced on-resistance compared to conventional laterally diffused MOS transistors may be implemented by using an SOI architecture and/or incorporating a substantially fully depleted portion of the conductive path between the source region and the drain region. As already discussed above, the SOI architecture may provide significant advantages with respect to a “bulk” architecture, in which a corresponding buried insulating layer is not available, since, in particular, the parasitic capacitance of a corresponding SOI transistor may be significantly reduced compared to a bulk transistor, while, at the same time, the presence of the buried insulating material may provide additional mechanisms for affecting the transistor behavior, for instance, by enabling the adjustment of a threshold voltage, providing an additional dynamic or static control mechanism for the channel region and the like. In other concepts disclosed herein, a portion of the conductive path between the source region and the drain region may be provided as a fully depleted semiconductor region, which per se, provides for a substantially linearly drop of an electric field along the length of the respective fully depleted semiconductor region. Furthermore, the probability of scattering events may be significantly reduced, thereby contributing to increased charge carrier speed, which, in turn, translates into a significantly reduced on-resistance. Consequently, with an appropriate adaptation of the length of the depleted “drift” region to the operating voltage, a corresponding increase of on-resistance, as may be typically observed in conventional devices, may be substantially avoided or may be significantly less pronounced due to the depleted nature of the drift region. Thereby, semiconductor devices including such field effect transistors may provide the potential for incorporating additional high power functionality into complex integrated circuits, while still preserving a high degree of compatibility with sophisticated CMOS techniques. In particular embodiments, the concept of the fully depleted drift region may be applied to an SOI architecture, thereby even further enhancing overall performance of a respective high power or high voltage transistor element compared to conventional LDMOS transistors.

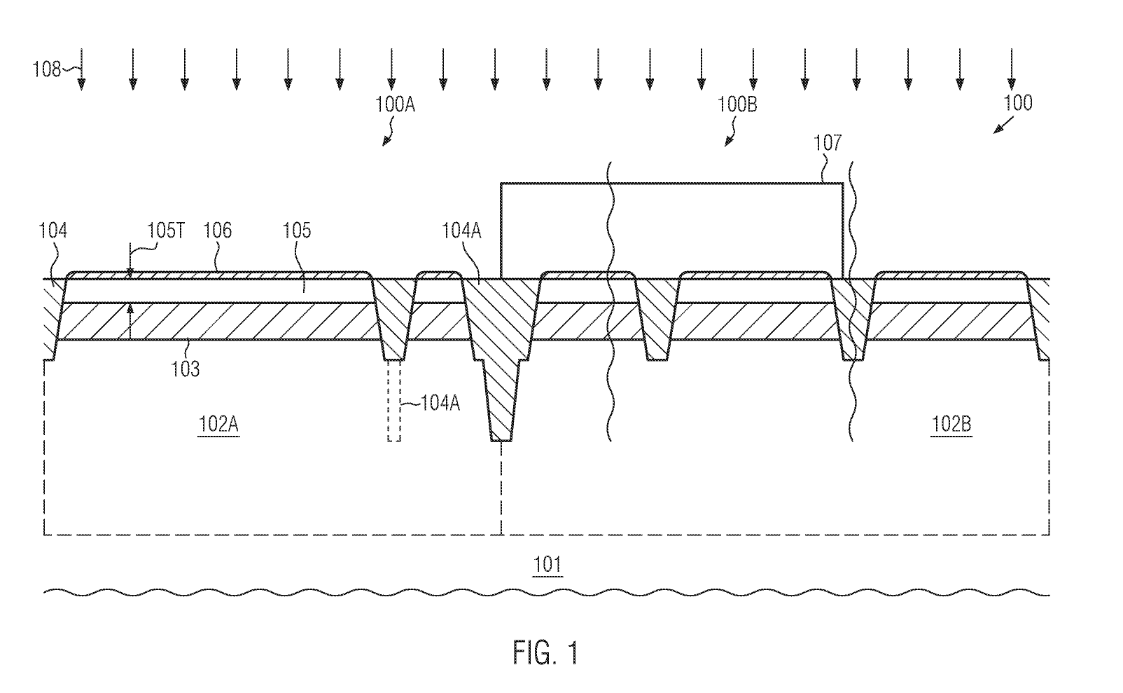

FIG. 1 schematically illustrates a cross-sectional view of a semiconductor device 100, which may comprise one or more device regions, wherein, for convenience, a first device region 100A and a second device region 100B are illustrated in FIG. 1. The first device region 100A may represent a device region in and above which a corresponding field effect transistor is to be formed that is appropriately adapted so as to accommodate increased operating voltage at a moderately low on-resistance, as already discussed above. For convenience, such a transistor may also be referred to as an LDMOS transistor. The second device region 100B may represent an area in the semiconductor device 100 in which other circuit elements, such as transistors, resistors, capacitors and the like, may be formed. For example, in some illustrative embodiments, the second device region 100B may represent a device region in and above which sophisticated low power transistor elements may be formed, wherein a high degree of compatibility with respect to the applied materials and/or manufacturing processes may be achieved with respect to materials and manufacturing techniques as may be used for forming the field effect transistor of increased operating voltage to be formed in and above the first region 100A. A low power transistor is to be understood as a transistor operating at approximately 5 V and less.

The semiconductor device 100 may comprise a substrate or a substrate material 101, which may be provided in the firm of silicon, silicon/germanium, germanium and the like. It should be appreciated that presently, in view of economic constraints, the majority of complex integrated circuits are currently produced on the basis of a silicon material as the basis semiconductor material. Therefore, in illustrative embodiments, the substrate or base material 101 may represent a crystalline silicon material. Moreover, a buried insulating layer 103, which may be formed of conventional dielectric materials, such as silicon dioxide, silicon nitride, silicon oxynitride, may be provided above the substrate material 101 and may therefore separate at least specific portions of a semiconductor layer 105 from the substrate material 101. It should be appreciated that the buried insulating layer 103 may be frequently provided as a single silicon dioxide layer of appropriate thickness, for instance, ranging from 10 to several 10s of nm in sophisticated SOI devices, while, in other cases, any other appropriate thickness may be used. Moreover, if required, in some illustrative embodiments, the buried insulating layer 103 may include two or more different materials when any such engineered state of the buried insulating layer 103, at least in certain device areas, is considered appropriate for enhancing performance and/or extending functionality of specific transistor elements.

It should be further appreciated that, in other illustrative embodiments (not shown), the substrate material 101 may be provided without the buried insulating layer, while, in other cases, in selected device areas, the buried insulating layer may be removed so as to form transistor elements on the basis of a bulk architecture. In the illustrative embodiment shown in FIG. 1, the buried insulating layer 103 may be provided at least across a portion of the semiconductor region 100A in and above which a field effect transistor is to be formed so as to have increased operating voltage capabilities and/or reduced on-resistance characteristics as discussed above. Similarly, in the embodiment shown in FIG. 1, one or more transistor areas in the device region 100B may be provided with the buried insulating layer 103 so as to form sophisticated low power transistor elements on the basis of an SOI architecture.

Furthermore, in this manufacturing stage, isolation structures 104, 104A may be provided so as to laterally delineate respective areas within the first and the second device regions 100A, 100B in accordance with overall design criteria. The isolation structures 104, 104A may represent shallow trench isolations including any appropriate dielectric material, such as silicon dioxide and the like, wherein, as illustrated, the isolation structures 104 may extend through the semiconductor layer 105, the buried insulating layer 103 and into the substrate material 101. The isolation structures 104A may have a similar configuration, but may, however, extend deeper into the substrate material 101, which may be considered appropriate for laterally delineating “hybrid” device regions, in which the buried insulating layer 103 is or will be removed at any appropriate manufacturing stage so as to provide a direct connection to the deeper-lying substrate material 101.

Furthermore, in this manufacturing stage, a protecting layer 106 may be formed at least on surface areas of the semiconductor layer 105, such as oxide, a silicon nitride material, or any combination thereof which may be considered appropriate for the further processing of the semiconductor device 100. In some illustrative embodiments, the semiconductor layer 105 may be provided with a thickness that allows the formation of a fully depleted semiconductor region within the semiconductor layer 105, possibly with a reduced overall dopant concentration, as already discussed above. To this end, in some illustrative embodiments, an initial thickness 105T of the semiconductor layer 105 may be selected to approximately 15 nm and less, wherein it should be appreciated that the thickness 105T may represent the thickness of the layer 105 at the manufacturing stage shown, i.e., after forming the isolation structures 104 and the protective layer 106. Although the thickness 105T may vary during the further processing of the device, in some illustrative embodiments, the thickness of the layer 105, in particular, during a final phase of the overall manufacturing process, will be at 15 nm or less. It should be appreciated that, in some illustrative embodiments, the application of, for instance, respective oxidation processes and/or cleaning processes may consume a certain amount of the initial semiconductor layer 105, thereby resulting in a more or less reduced overall thickness. As will be discussed in more detail later on, certain portions of the semiconductor layer 105 may experience an increase of thickness by epitaxially depositing further semiconductor material, wherein, however, at least a specific portion of the layer 105, which may represent a corresponding channel region of a field effect transistor still to be formed, may still have a thickness that is defined in some illustrative embodiments by the above-specified range.

Furthermore, in the manufacturing state shown in FIG. 1, a mask 107, for instance, formed of any appropriate material, such as resist material, polymer material and the like, may be provided so as to cover certain areas of the semiconductor device 100. For instance, the mask 107 may represent an implantation mask used during one or more implantation processes 108 designed for incorporating a desired dopant species into the substrate material 101, thereby forming respective doped regions 102A, 102B in the first and second device regions 100A, 100B, respectively. For example, any such doped regions may be indicated as deep well regions and may be formed in the process of forming one or more different types of low power transistor elements in the second device region 100B on the basis of well-established process recipes. Moreover, if required, one or more additional implantation processes based on a corresponding complementary mask may be performed so as to form further deep well regions in the second device region 100B, if required. As previously discussed, in sophisticated SOI transistor elements, as may be formed in and above the second device region 100B, respective doped regions positioned below the buried insulating layer 103 may be efficiently used for adjusting the threshold voltage and/or providing an additional control mechanism for controlling conductivity in a corresponding channel region. Since any such mechanisms may, in some illustrative embodiments, also be advantageously implemented in the first device region 100A, a high degree of process compatibility may be achieved, thereby merely requiring a specific modification of a corresponding lithography mask that is used for forming the respective implantation masks, such as the mask 107.

A typical process flow for forming the semiconductor device 100 as shown in FIG. 1 may include the following processes. The substrate material 101, including the buried insulating layer 103 and the initial semiconductor layer 105, for instance, in the form of a thin silicon layer, may be provided as a specific SOI substrate or may be specifically formed on the basis of well-established process techniques, for instance, when the SOI configuration is only to be provided in specific areas of the semiconductor device 100. Moreover, if required, a corresponding engineering of the buried insulating layer 103 may be implemented into the process flow, if considered appropriate. Thereafter, the isolation structures 104, 104A may be formed, for instance, by applying respective lithography, etch and oxidation and/or deposition techniques, followed by sophisticated planarization processes, thereby obtaining a substantially planar typography. The protective layer 106 may be formed prior to, during and/or after forming the isolation structures 104, 104A, for instance, by oxidation, deposition or any combination thereof. Next, a lithography process may be applied so as to form the implantation mask layer 107, followed by a respective implantation process or process sequence, such as the process 108, thereby obtaining the doped regions 102A, 102B. As discussed above, respective doped regions of inverse conductivity type may also be formed on the basis of a corresponding sequence of lithography processes and implantation processes in accordance with overall device requirements. If required, the semiconductor device 100 may be annealed in order to activate the implanted dopants, while, in other cases, a respective dopant activation may be performed in a later manufacturing stage.

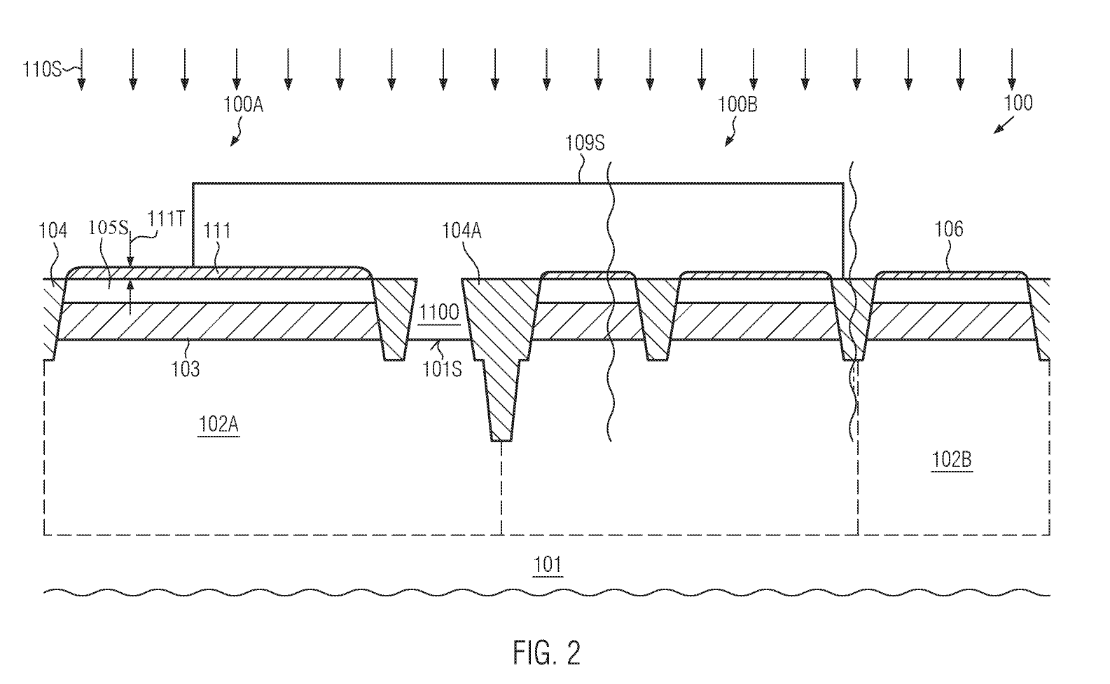

FIG. 2 schematically illustrates a cross-sectional view of the semiconductor device 100 in a further advanced manufacturing stage. As shown, in some illustrative embodiments, a protective layer 111 may be formed above the semiconductor layer 105 in combination with or alternative to the protective layer 106, which may still be present in the device region 100B. The protective layer 111 may be formed of any appropriate material, such as silicon dioxide, silicon nitride, any combination thereof, and the like, and may provide superior conditions during an implantation process 110S, which may be performed on the basis of an implantation mask 109S, provided in the form of a resist material and the like. Furthermore, in some illustrative embodiments, an opening 1100 may be formed between respective structures 104, 104A so as to expose a surface 1015 of the substrate material 101. As previously discussed, the opening 1100 may represent a “hybrid” area of the semiconductor device 100, in which the buried insulating layer 103 may be removed so as to provide a connection to the substrate material 101, for instance, to the doped region 102A, as will be described later on in more detail.

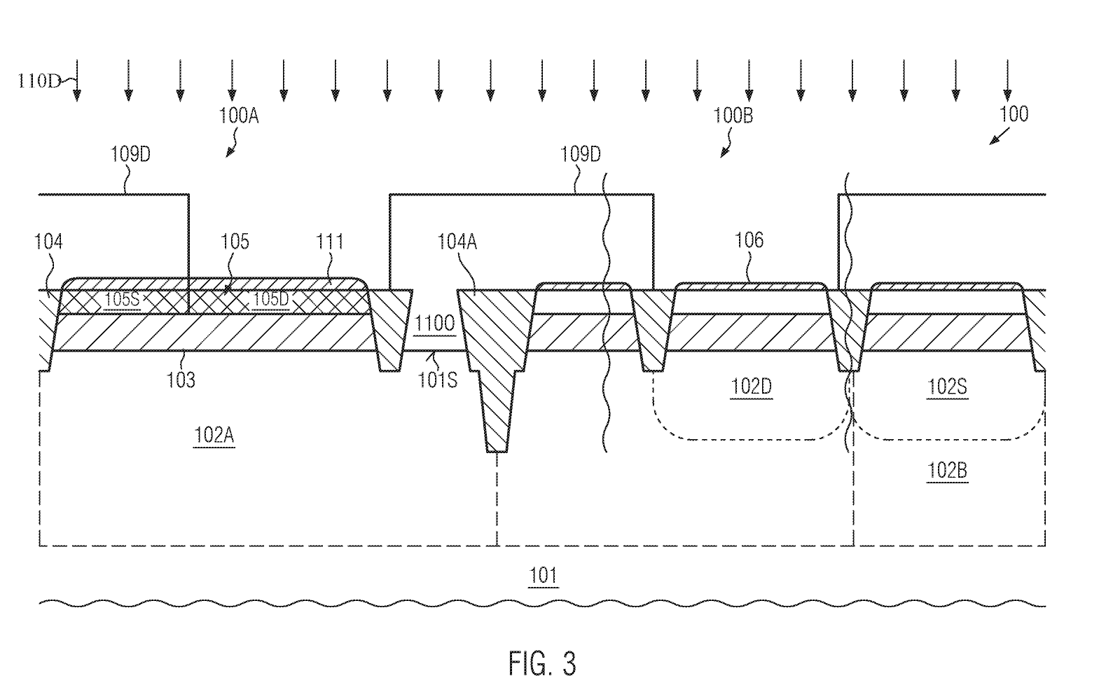

The semiconductor device 100 as shown in FIG. 2 may be formed on the basis of the following process steps. In some illustrative embodiments, the protective layer 111 may be omitted when process conditions for the implantation process 110S are appropriately selected so as to enable incorporation of an appropriate dopant species into the underlying semiconductor layer 105 without causing undue implantation-induced damage therein. In other illustrative embodiments, as shown, the protective layer 111 may be formed by any well-established deposition technique, such as a process for depositing silicon dioxide and the like, while, in other illustrative embodiments, if a respective consumption of material of the semiconductor layer 105 in the first and second semiconductor regions 100A, 100B is acceptable, an oxidation process may be performed so as to additionally grow material on the layer 106, if provided, in the form of an oxide material. In some illustrative embodiments, providing the protective layer 111 may include an adjustment of a thickness 111T thereof, such that an appropriate deposition of the dopant species incorporated by the process 110S may be controlled on the basis of the layer 111 in order to obtain a desired dopant concentration within a region 105S of the semiconductor layer 105 exposed by the implantation mask 109. That is, in some illustrative embodiments, the thickness 111T may be adapted to the process parameters as applied during the implantation process 110S, which, in turn, is appropriately designed so as to form a further doped region 102S (see FIG. 3) in any non-masked areas of the second device region 100B, in which a respective dopant species may be required, for instance, for adjusting threshold voltage characteristics and the like, as previously discussed.

For instance, in one area of the second device region 100B, in which a low power transistor element is to be formed, a doped region 102S may be formed on the basis of the implantation process 110S, while, on the other hand, a desired dopant concentration and positioning of the dopant species in the region 105S may be accomplished by appropriately selecting the thickness 111T. To this end, simulation models may be used and/or experiments may be performed in order to obtain the desired depth and concentration within the doped region 102S in the second device region 100B, while also obtaining a desired moderately low dopant concentration in the region 105S. Consequently, in any such embodiments, additional masking steps may be avoided, since the doped region 102S may need to be formed anyway with respect to overall performance of any low power transistor elements still to be formed. In other cases, the implantation mask 109S, as well as the implantation recipe for the process 110S may be specifically designed to incorporate the dopant species into the portion 105S, while any doped well regions for low power transistors in the second device region 100B may be formed in separate process steps.

It should be appreciated that the opening 1100 may be formed at any appropriate point in time, for instance, prior to or after forming the doped portion 105S, for instance, prior to or after forming the isolation structures 104, 104A on the basis of respective, well-established patch recipes.

FIG. 3 schematically illustrates the semiconductor device 100 when subjected to a further implantation process 110D that is performed on the basis of a further implantation mask 109D. During the implantation process 110D, a respective dopant species may be incorporated into an exposed portion of the layer 111 and into the semiconductor layer 105, thereby forming a doped portion 105D within the semiconductor layer 105. It should also be appreciated that the implantation process 110D may be performed on the basis of specifically selected process parameters so as to obtain the desired dopant concentration in the portion 105D, wherein the protective layer 111 may be provided or may be omitted, depending on the overall process strategy. In some illustrative embodiments, the implantation process 110D and, thus, the implantation mask 109D, may be selected such that a high degree of process compatibility may be obtained with respect to any low power transistor elements to be formed in the second device region 100B. That is, similar to the implantation process 110S described with reference to FIG. 2, also in this case, a required doped region 102D may be formed below an area in the second device region 100B, in and above which a respective low power transistor element may have to be formed, requiring the specifically-doped well region 102D for adjusting transistor characteristics, as discussed above. Consequently, when appropriately selecting the characteristics of the protective layer 111, during the same implantation process 110D, the regions 102D and the doped portions 105D may be formed in the first and second device regions 100A, 100B, respectively. Consequently, in any such embodiments providing a high degree of process compatibility, the number of lithography steps required for forming respective implantation masks may not have to be increased compared to a process flow for forming the low power transistor elements in the second device region 100B. The doped portions 105D, 105S have inverse conductivity type so as to form a PN junction, as will be described later on in more detail.

The further processing may be continued, for instance, by removing the implantation mask 109D on the basis of well-established resist removal techniques, followed by the removal of the layer 111, if provided, and the protective layers 106. To this end, well-established cleaning recipes are available.

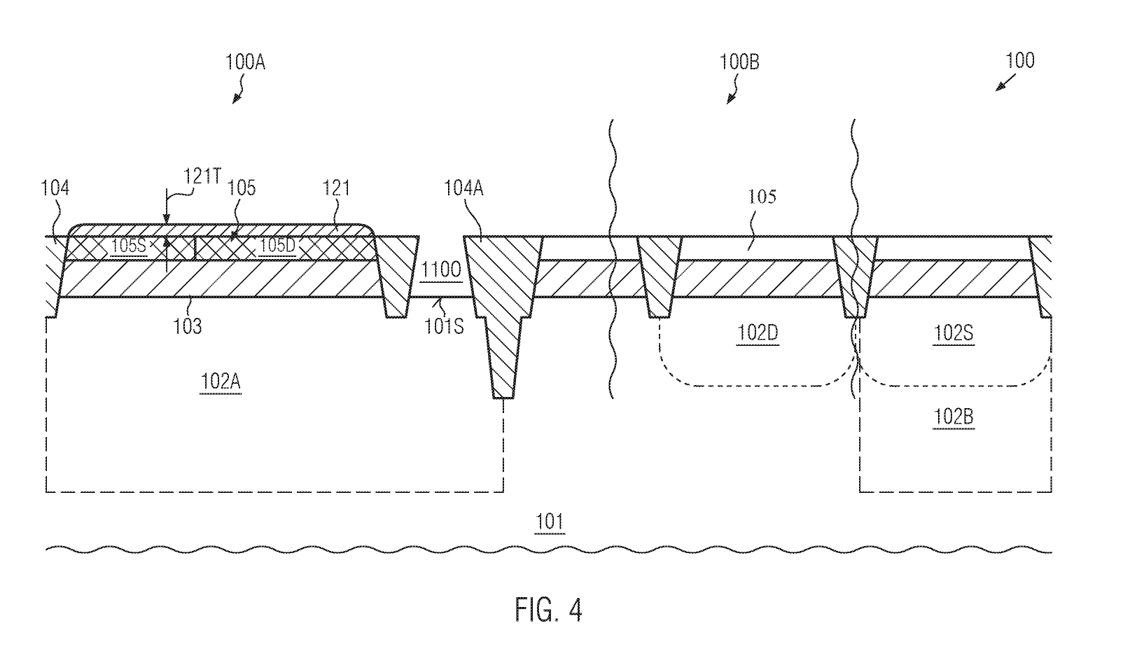

FIG. 4 schematically illustrates the semiconductor device 100 in a further advanced manufacturing stage. As illustrated, a dielectric layer 121 may be formed above the semiconductor layer 105 in the first semiconductor region 100A, while, in the second semiconductor region 100B, the semiconductor layers 105 may be exposed or may have a protective layer, such as an oxide layer, of significantly reduced thickness (not shown) compared to the dielectric layer 121. Since the layer 121 may act as a portion of a dielectric material of a gate electrode structure of a transistor still to be formed upon the basis of the semiconductor layer 105 having the portions 105D, 105S, a respective thickness 121T of the layer 121 may be selected in view of the material characteristics of the layer 121 and with respect to overall transistor characteristics, such as breakdown voltage and the like. For example, the dielectric layer 121 may be provided in the form of a silicon dioxide material, a silicon nitride material, a silicon oxynitride material, or any combination thereof, with a thickness of approximately 3 nm to several nm and even greater, depending on the required breakdown voltage. The dielectric layer 121 may be formed on the basis of any appropriate process technique, for instance, depositing an appropriate dielectric material based on well-established process recipes, while, in other cases, in addition or alternative to depositing the dielectric material of the layer 121, an oxidation process may be performed, if a corresponding consumption of material of the semiconductor layers 105 has been taken into account in the initial layer thickness of the layer 105. After forming the layer 121, a masked etch process may be applied, for instance, on the basis of well-established wet chemical etch recipes, plasma-assisted etch recipes and the like, in order to substantially preserve the material 121 in the first semiconductor region 100A, while removing at least a significant portion of the layer 121 from above the semiconductor layers 105 in the second semiconductor region 100B. In other illustrative embodiments, the layer 121 may be removed from above the region 100B in a later stage, as will be described later on in more detail.

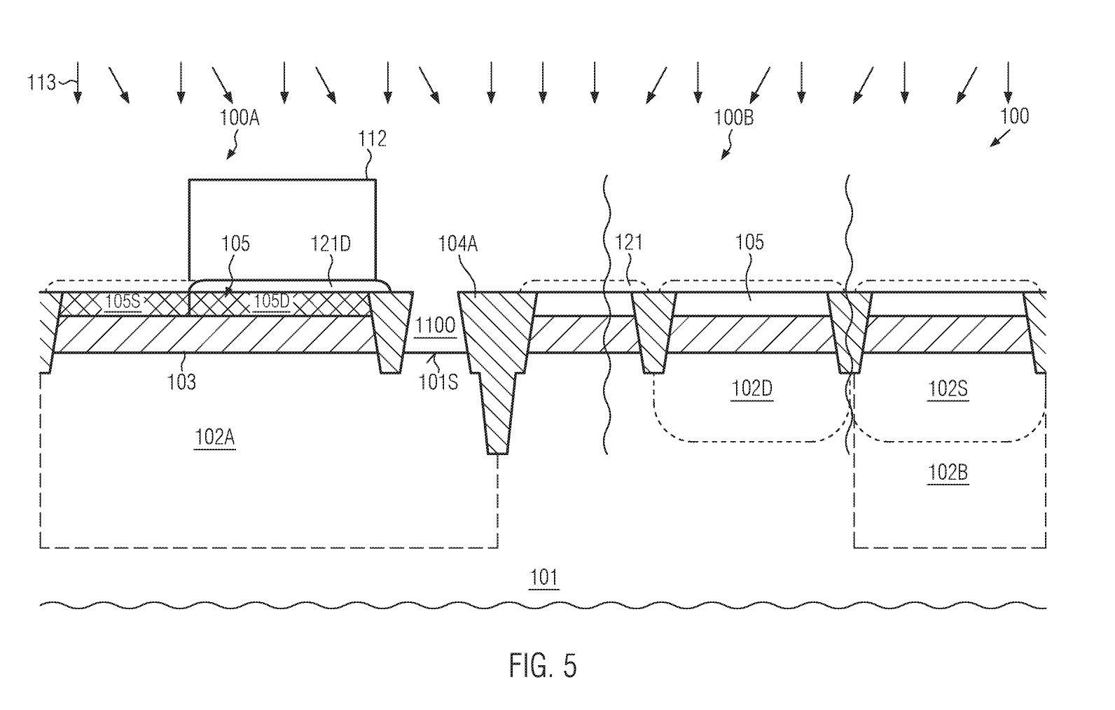

FIG. 5 schematically illustrates a cross-sectional view of the semiconductor device 100 according to further illustrative embodiments. As illustrated, the device 100 is exposed to an etch ambient 113, for instance, a wet chemical etch ambient, a plasma-assisted ambient, or any combination thereof, and the like. Furthermore, an etch mask 112, such as a resist material and the like, may be provided so as to cover a respective portion 121D of the dielectric layer 121. In some illustrative embodiments, the layer 121 may have already been removed from surface portions of the second semiconductor region 100B, as discussed above with respect to FIG. 4, while, in other illustrative embodiments, the dielectric layer 121 may still be formed on respective surface areas of the semiconductor layers 105 in the first and second device regions 100A, 100B, as indicated by the dashed lines. Thus, upon exposing the semiconductor device 100 to the etch ambient 113, any non-masked areas of the semiconductor device 100 may be prepared for the formation of a “standard” dielectric material for respective gate electrode structures.

That is, in the embodiment shown in FIG. 5, the process 113 may include any required process steps for removing any protective layers from the surface areas of the semiconductor layer 105, except for the portion 105D formed in the first semiconductor region 100A that is covered by the etch mask 112. Consequently, by appropriately dimensioning the mask 112 in accordance with dimensions as may have been previously used upon forming the doped regions 105S, 105D, including respective dopant species of opposite conductivity type, the dielectric material 121 may be removed above the portion 105S and may be preserved above the portion 105D. Concurrently, any exposed surface portions of the semiconductor layers 105 in the second device region 100B may be exposed and may additionally be cleaned and, thus, prepared for the subsequent deposition of a further gate dielectric material. It should be appreciated that, during the process 113, any dielectric material within the opening 1100 may also be removed, if any such material has been formed or deposited during the preceding process sequence. It should be further appreciated that appropriate process recipes for the process 113 are well established in the art, since any such processes may be typically required for forming sophisticated gate electrode structures, including, for instance, high-k dielectric materials in combination with metal-containing materials.

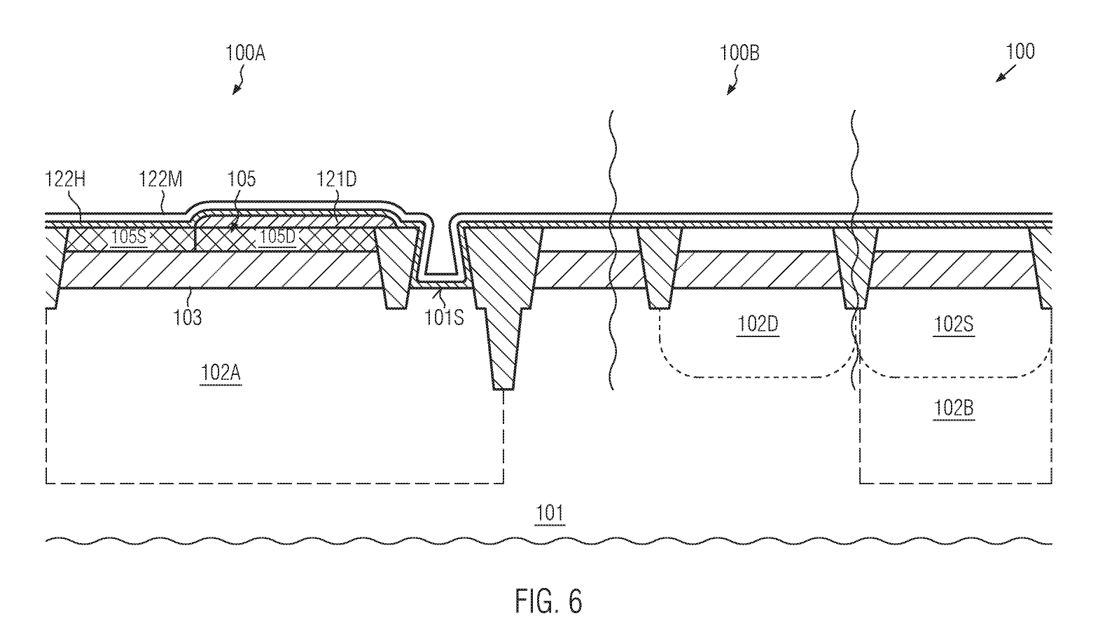

FIG. 6 schematically illustrates a cross-sectional view of the semiconductor device 100 in a further advanced manufacturing stage. As shown, one or more layers 122H, 122M may be formed on exposed surface areas of the semiconductor device 100 and may represent respective material layers of sophisticated gate electrode structures still to be formed. For instance, the layer 122H may include any appropriate dielectric material, for instance, in some illustrative embodiments, including a high-k dielectric material, for instance, based on hafnium oxide and the like, possibly in combination with “conventional” dielectric materials, such as silicon dioxide, silicon oxynitride, silicon nitride and the like. Furthermore, the material layer 122M may include any required atomic species for additionally adjusting a threshold voltage and generally providing material characteristics as required in sophisticated high-k metal gate electrode structures. For instance, the layer 122M may include metal species for threshold adjusting, for providing barrier characteristics, increasing overall conductivity of an electrode material, and the like. Forming the layers 122H, 122M may be accomplished on the basis of well-established process techniques, including, for instance, oxidation and deposition, such as atomic layer deposition (ALD) and the like. In this manner, the step-like configuration of the surface in the first device region 100A may be reliably covered by the layers 122H, 122M, thereby forming a graded material profile. Consequently, the sophisticated gate materials may be formed on the exposed portion 105S in the first device region 100A and may also be formed on any exposed surface areas of the semiconductor layer 105 in the second device region 100B. On the other hand, the corresponding gate materials may also be formed on the portion 121D which essentially determines the physical thickness and, thus, robustness, with respect to high voltages and charge carrier injection into a gate dielectric material for the gate electrode structure still to be formed. Consequently, at least the dielectric materials in the form of the layer 121D and at least the layer 122H may provide for a graded or stepped thickness of the resulting gate dielectric material, wherein the thickness and characteristics above the semiconductor portion 105S are designed in view of high capacitive coupling, whereas the dielectric material formed above the portion 105D may exhibit a significantly increased physical thickness, thereby ensuring the required robustness with respect to voltage and charge carrier injection.

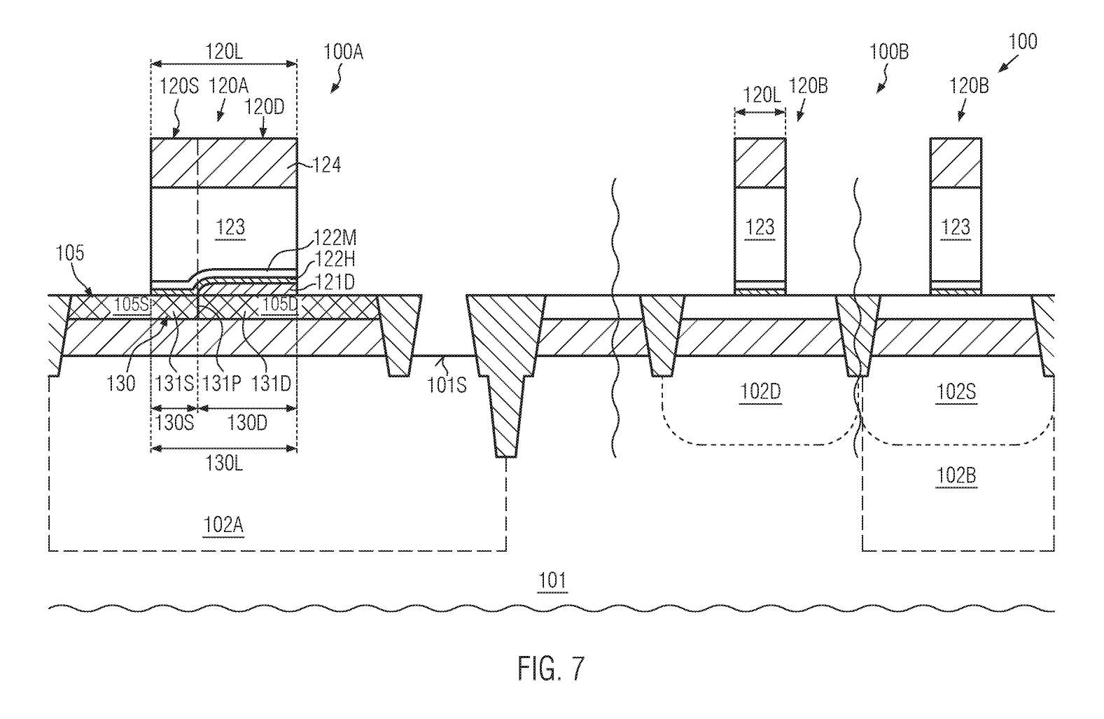

FIG. 7 schematically illustrates a cross-sectional view of the semiconductor device 100 in a further advanced manufacturing stage. As illustrated, respective gate electrode structures 120A, 120B may be formed on the respective semiconductor layers 105 of the first and second device regions 100A, 100B, respectively. The gate electrode structure 120A may comprise a first gate portion 120S, which is formed on a portion of the semiconductor region 105S and which may comprise the gate materials 122H, 122M, thereby providing for high capacitive coupling, as discussed above. Furthermore, a second gate portion 120D formed above a portion of the semiconductor layer 105D may additionally comprise the relatively thick gate dielectric material 121D, thereby imparting superior robustness to this portion of the gate electrode structure, as already discussed above. Furthermore, in this manufacturing stage, the gate electrode structure 120A and, thus, the portions 120S, 120D may comprise a further electrode material 123, in addition to any metal material that may be included in the layer 122M, such as polysilicon, amorphous silicon, amorphous germanium, silicon/germanium and the like. Furthermore, a dielectric cap material 124, such as silicon nitride, may be formed on the electrode material 123.

Similarly, the gate electrode structures 120B formed in the second device region 100B may have a configuration similar to the gate portion 120S of the gate electrode structure 120A. It should be appreciated, however, that a length 120L of the gate electrode structures 120B may significantly differ from the corresponding length 120L of the gate electrode structure 120A, since, as discussed above, the gate electrode structure 120A may represent a part of a transistor for high voltage applications, thereby requiring a significant increase of the transistor length so as to provide for a smooth drop of an electric field along the length direction of a corresponding transistor, as already discussed above. Consequently, by selecting an appropriate length of the gate electrode structure 120A and by selecting respective lengths of the gate portions 120S, 120D, a corresponding adaptation of transistor characteristics with respect to breakdown voltage, on-resistance and the like may be obtained. That is, by selecting the gate length 120L of the structure 120A, the length of a channel region 130, indicated as 130L, may, thus, be defined.

Thus, the channel region 130 may be formed of the semiconductor portions 105S, 105D that are covered by the gate electrode structure 120A. Consequently, the channel region 130 may comprise a first portion 131S corresponding to the portion of the semiconductor region 105S covered by the gate portion 120S, and may comprise a second channel portion 131D formed by the portion of the semiconductor region 105D covered by the second gate portion 120D. Hence, the channel region 130 may comprise a PN junction 131P defined by the boundary between the channel portion 131S and the channel portion 131D. For instance, for an N-type transistor to be formed on the basis of the gate electrode structure 120A, the channel portion 131S may have incorporated therein a P-type dopant species at a moderately low concentration, while the second channel portion 131D may have a dopant species of inverse conductivity type with a moderately low concentration, as is already discussed above. Furthermore, as also explained above, in some illustrative embodiments, the thickness of the channel region 130, which may substantially correspond to the thickness 105T (see FIG. 1) of the initial semiconductor layer 105, may be selected so as to obtain a fully depleted semiconductor region, thereby providing, in particular, the channel portion 131D as a low-doped region with reduced thickness so as to establish a fully depleted state. Consequently, due to the fully depleted nature, a corresponding voltage and, thus, electric field may substantially linearly drop along a length of the channel portion 131D. Therefore, by selecting a length 130D of the channel portion 131D in accordance with a required breakdown voltage, different types of power transistors may be formed in the device region 100A, by appropriately adjusting the length 130B. Similarly, a length 130S of the channel portion 131S may be appropriately selected so as to obtain the desired channel controllability for forming a conductive channel upon applying a specific control voltage. Consequently, the characteristics of a transistor still to be formed on the basis of the gate electrode structure 120A may be adjusted in a well-adjustable manner by appropriately selecting respective transistor dimensions, in particular, the respective length dimensions of the first and second channel portions 131S, 131D. It should be appreciated that the channel length 120L of the gate electrode structure 120A, i.e., the sum of the channel lengths 130D and 130S, may range from approximately 100 nm to several hundred nm and even greater, depending on the voltage drop required.

On the other hand, the gate length 120L of the gate electrode structures 120B may be selected in accordance with requirements for any low power transistors still to be formed in the second device region 100B.

The gate electrode structures 120A, 120B as shown in FIG. 7 may be formed in accordance with well-established process techniques, including the deposition of the electrode material 123 followed by the deposition of the cap material 124 and applying sophisticated lithography and etch techniques for patterning the resulting gate electrode layer stack. It should be appreciated that the respective patterning sequence may be appropriately modified so as to take into account the increased thickness of the dielectric material within the second gate portion 120D of the gate electrode structure 120A. That is, a corresponding over-etch time and the like may be efficiently applied so as to reliably expose the surface area of the semiconductor layer 105D, above which the dielectric material of increased thickness of the gate portion 120D has to be removed.

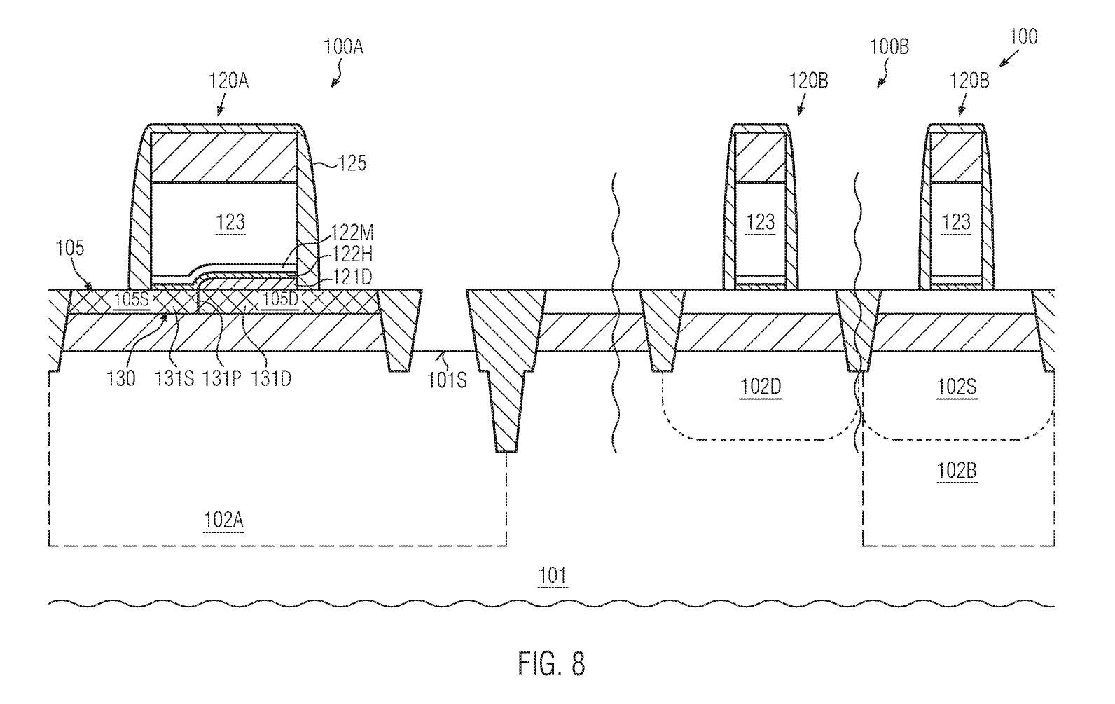

FIG. 8 schematically illustrates the semiconductor device 100 in a manufacturing stage in which sidewall spacers 125 may be formed on sidewalls of the gate electrode structures 120A, 120B, which may be accomplished by depositing any appropriate spacer material, such as silicon nitride and the like, and performing a plasma-assisted etch process so as to remove the spacer material from “horizontal” surface areas of the semiconductor layer 105 that are not covered by the respective gate electrode structures 120A, 120B. It should be appreciated that various masking schemes may be applied so as to form the spacers 125 for the gate electrode structures 120A and 120B. For instance, when the gate electrode structures 120B may represent the gate electrode structures of transistors of different conductivity type, a spacer material may be deposited, a mask layer may be formed so as to cover the gate electrode structure of one type of transistor, and thereafter a first spacer etch may be performed. After removal of the etch mask, a further spacer layer may be deposited, a further mask layer may be formed and spacer elements may be etched, while the other gate electrode structure is covered by the further spacer layer. In this manner, the latter gate electrode structure may have spacer elements and exposed semiconductor areas laterally adjacent thereto, which may receive an epitaxially grown semiconductor material, while the semiconductor material in the vicinity of the other type of gate electrode is still covered by the further spacer layer, which may act as growth mask.

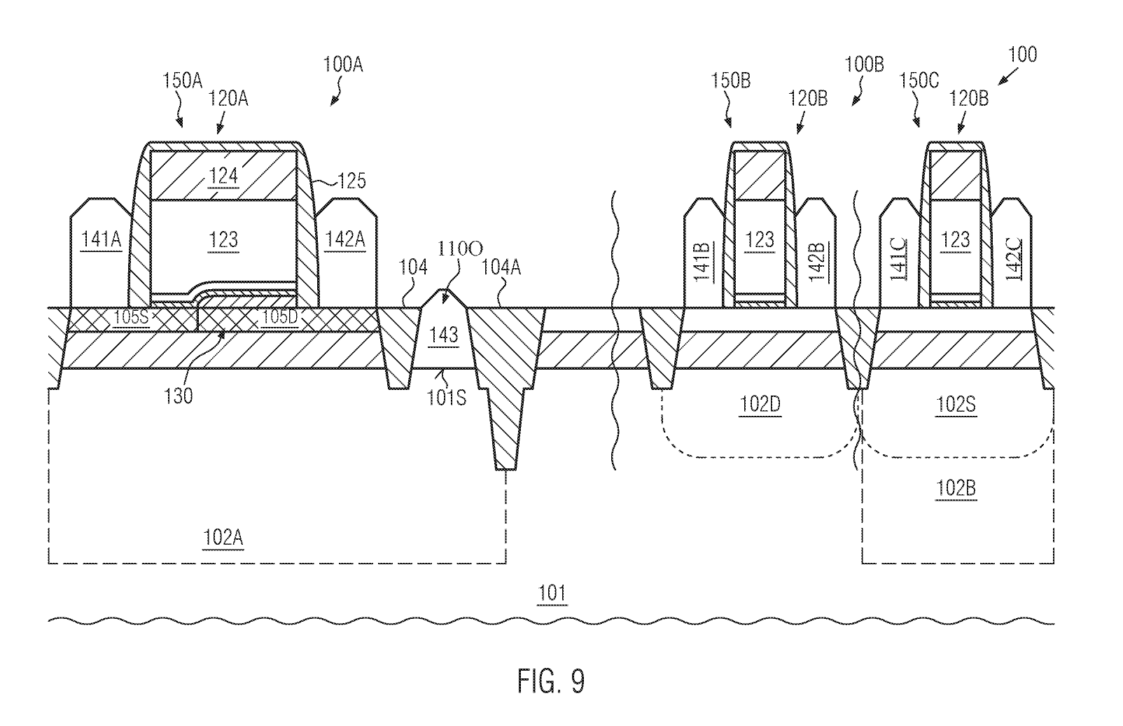

FIG. 9 schematically illustrates the semiconductor device 100 in a further advanced manufacturing stage. As illustrated, a transistor 150A, which may also be referred to as a high voltage or laterally diffused transistor, may be formed in and above the first semiconductor region 100A on the basis of the gate electrode structure 120A and may comprise a raised source region 141A and a raised drain region 142A, which may be provided in the form of a highly doped crystalline semiconductor material grown on exposed portions of the semiconductor portions 105S, 105D, respectively. For example, the drain and source regions 142A, 141A may be provided in the form of a highly N-doped semiconductor material, such as silicon and the like, when the transistor 150A is to represent an N-type transistor. Similarly, transistors 150B, 150C may be formed on the basis of the respective gate electrode structures 120B and may comprise raised drain and source regions 142B, 141B and 142C, 141C, respectively. For instance, the transistor 150C may represent an N-type transistor, including the raised drain and source regions 142C, 141C in the form of a highly N-doped silicon material. Furthermore, the well region 102S may be provided in the form of a low-doped P-region, for instance, for appropriately adjusting threshold voltage and other transistor characteristics, as discussed above. The transistor 150B may represent a P-type transistor with highly P-doped semiconductor material in the drain and source regions 142B, 141B. Similarly, the well region 102D may represent a moderately low-doped N-type region for adjusting specific transistor characteristics. Furthermore, a highly doped semiconductor material 143 may be provided in the previously formed opening 1100 (FIG. 2), thereby providing a contact region for connecting to the body or well region 102A, if any such connection is required, for instance, in view of superior controllability of the channel region 130, adjusting threshold voltage characteristics and the like.

The device 100 as shown in FIG. 9 may be formed on the basis of the following processes. A first type of highly conductive semiconductor material may be grown on exposed surface areas of the respective portions of the semiconductor layer 105, while other portions may be covered by an appropriate growth mask, for instance, provided in the form of oxide, silicon nitride and the like. Thereafter, the growth mask may be removed and the previously formed raised drain and source regions may be capped with a further growth mask material, followed by a further selective epitaxial growth process. In other cases, a masking regime may be applied on the basis of spacer layers, as also discussed in the context of FIG. 8. Thereafter, any cap material may be removed, for instance, by well-established wet chemical etch recipes and the like.

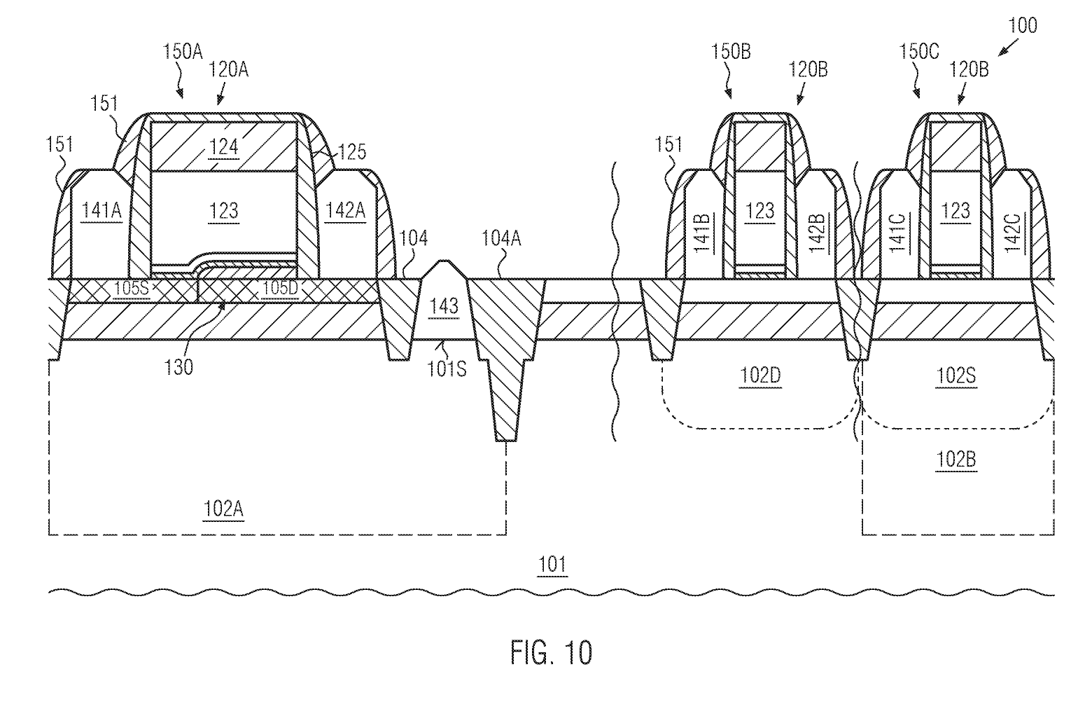

FIG. 10 schematically illustrates a cross-sectional view of the semiconductor device 100 in a manufacturing stage in which spacer elements 151 may be formed on exposed sidewall portions of the raised drain and source regions 142A, 141A, 142B, 141B, 142C, 141C and exposed sidewall portions of the gate electrode structures 120A, 120B. The spacers 151 may be formed of any appropriate material having a moderately high etch selectivity with respect to, for instance, the spacers 125 and the cap layer 124. The spacers 151 may be formed on the basis of well-established deposition techniques for forming, for instance, silicon dioxide material, followed by respective anisotropic etch processes for removing the oxide material from substantially horizontal surface portions. Thereafter, an appropriate etch recipe may be applied so as to remove the cap layer 124 together with respective portions of the sidewall spacers 125, which may be accomplished on the basis of well-established wet chemical etch recipes for etching, for instance, silicon nitride material, thereby also removing portions of the spacers 151 formed on the spacers 125 due to the increased etch attack compared to the spacers 151 formed on sidewalls of the raised drain and source regions.

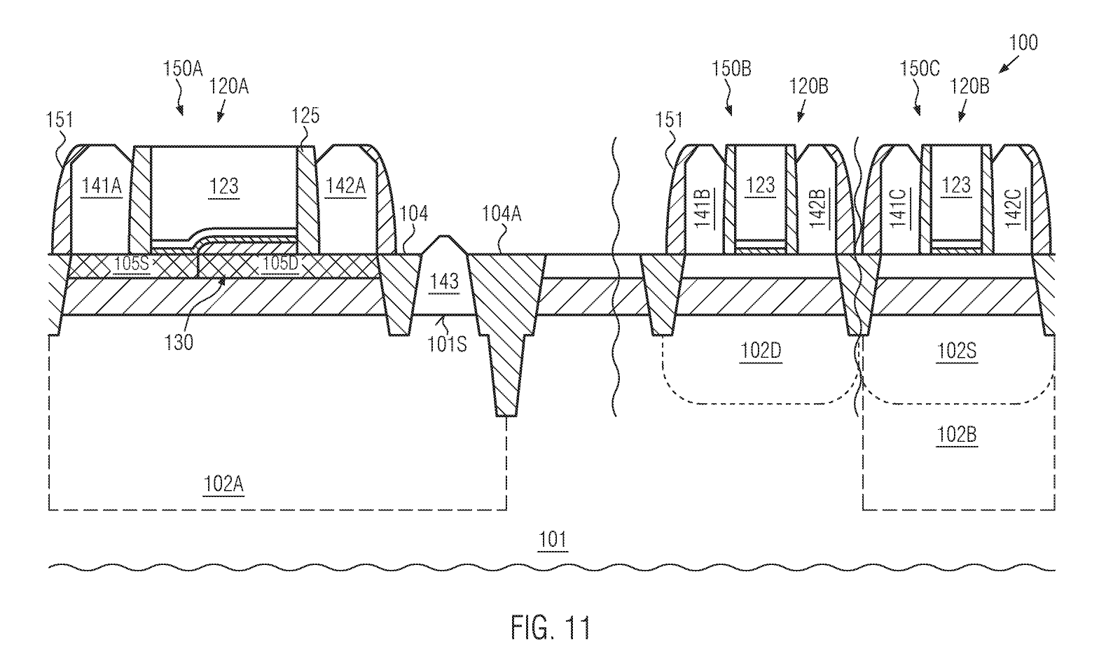

FIG. 11 schematically illustrates the semiconductor device 100 after the above-described process sequence. That is, the device 100 may comprise the transistor 150A with the gate electrode structure 120A, in which the electrode material 123 is exposed and is reliably separated from the respective source and drain regions 141A, 142A by the sidewall spacers 125. The gate electrode structures 120B of the transistors 150B, 150C may have a similar configuration, except for a reduced gate length and a gate dielectric material of substantially identical thickness along the entire length of the gate electrode structures 120B. In this manufacturing stage, the further processing may be continued by forming a highly conductive semiconductor metal compound in exposed areas of any exposed semiconductor regions, such as the raised and source and drain regions 141A, 142A, 141B, 142B, 141C, 142C, the gate electrode material 123 and the region 143, if provided. To this end, well-established process strategies are available for forming a nickel silicide material by depositing a nickel material and performing respective anneal processes in order to obtain the desired metal semiconductor compound, followed by the removal of any excess material. In this manner, any contact resistance to the respective semiconductor materials may be significantly reduced.

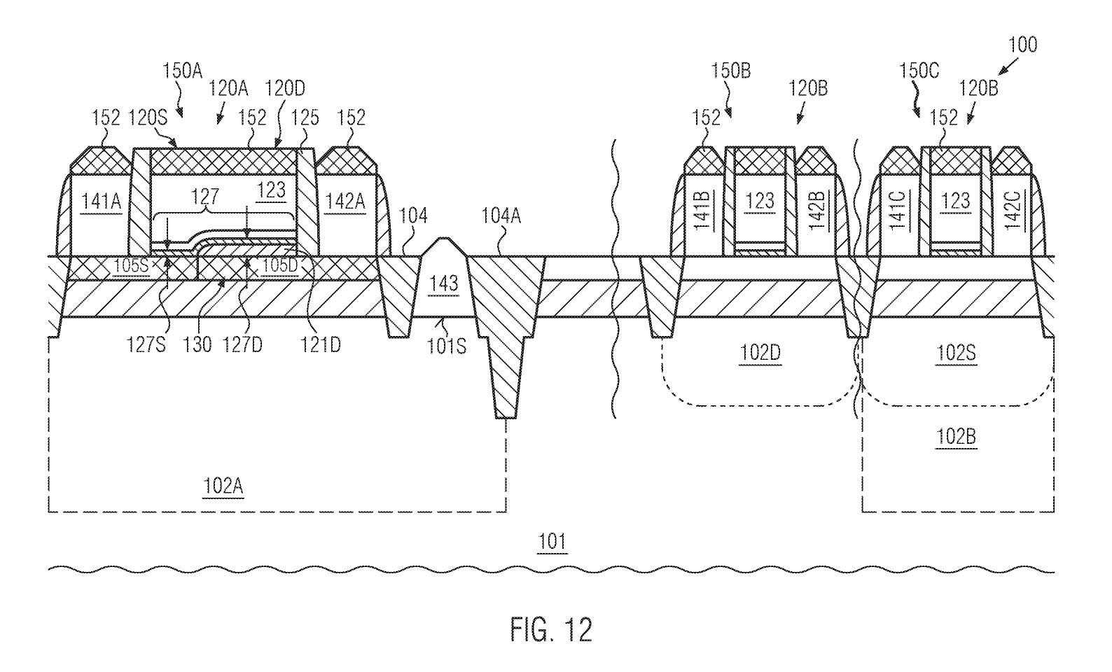

FIG. 12 schematically illustrates a cross-sectional view of the semiconductor device 100 after completing the above-described process sequence. Consequently, respective semiconductor metal compound regions, such as nickel silicide regions 152, may be formed in exposed surface areas of semiconductor regions. That is, the drain and source regions 142A, 141A of the transistor 150A, the drain and source regions 142B, 141B of the transistor 150B, and the drain and source regions 142C, 141C of the transistor 150C may comprise the metal silicide regions 152. Similarly, the gate electrode structures 120A, 120B, that is, the silicon-containing electrode materials 123 thereof, may also comprise the metal silicide regions 152. Also, the region 143, if provided, may have formed therein the metal silicide region 152.

On the basis of the device configuration as shown in FIG. 12, the further processing may be continued by depositing any appropriate interlayer dielectric material, such as silicon dioxide, silicon nitride and the like, and patterning the same so as to form contact openings and to connect to the various transistor regions. Thereafter, the respective contact openings may be filled with any appropriate conductive material, followed by the formation of one or more additional metallization layers.

Consequently, the transistor 150A representing a high voltage or high power transistor may be provided with the gate electrode structure 120A having the gate portion 120S adjacent to the source region 141A and the gate portion 120D adjacent to the drain region 142A. The gate portion 120S comprises a gate dielectric material, collectively indicated for the entire gate electrode structure 120A by 127, with a configuration similar to the gate electrode structures 120B of the low power transistor elements 150B, 150C, thereby providing superior channel controllability. That is, the dielectric material 127 of the gate portion 120S may comprise a high-k dielectric material in combination with metal species, barrier materials and the like, as is typically required for forming sophisticated gate electrode structures with superior capacitive coupling and channel controllability, wherein the physical thickness is relatively small.

On the other hand, the dielectric material 127 of the gate portion 120D may comprise the additional gate dielectric layer 121D (FIG. 7) in addition to the sophisticated gate dielectric materials, thereby providing for superior robustness with respect to charge carrier injection and breakdown voltage. Thus, a physical thickness 127S of the gate dielectric material 127 in the first gate portion 120S is less compared to a thickness 127D of the gate dielectric material 127 in the second gate portion 120D. Furthermore, in particular, the channel portion 131D, which may have a fully depleted configuration in some illustrative embodiments, may provide for high charge carrier speed and, thus, low on-resistance, while at the same time providing efficient and linear voltage drop due to the relation E=V/L, wherein E is the strength of the electrical field, V is the voltage between drain 142A and source 141A during operation of the transistor 150A, and L is the length of the channel portion 131D, also previously indicated as 130L (FIG. 7).

As a result, the present disclosure provides a transistor architecture and a corresponding manufacturing sequence in which a field effect transistor with high breakdown voltage and low on-resistance may be formed on the basis of the design of a laterally diffused MOS transistor, in which a respective PN junction, such as the PN junction 131P (see FIG. 8), may be formed below the respective gate electrode structure. The PN junction, i.e., the interface of the channel portions of inverse conductivity type, may be formed prior to forming the gate electrode structure, wherein a high degree of process compatibility may be preserved with respect to the formation of sophisticated low power transistor elements. Furthermore, in order to further enhance transistor characteristics with respect to breakdown voltage and charge carrier injection, a significant portion of the gate electrode structure may have incorporated therein the gate dielectric material of increased thickness, which may be formed on the basis of a process sequence so as to require only slight modifications of the overall process flow. Furthermore, by providing initial semiconductor material for the channel regions with reduced thickness and relatively low dopant concentration, a fully depleted configuration may be established in some illustrative embodiments, thereby obtaining a “drift” region in which an electrical field may drop in a linear manner, while high charge carrier speed may still provide a desired low on-resistance. In some illustrative embodiments, the channel region is formed on a buried insulating material, thereby even further enhancing overall characteristics of the high voltage transistor. Due to superior adjustability with respect to operating voltage, without unduly affecting the moderately low on-resistance, the high voltage transistor of the present disclosure is well-suited for implementation in sophisticated circuit designs, in particular requiring RF amplifiers and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A semiconductor device, comprising:
a laterally diffused field effect transistor including:
a first channel portion of a channel region having a first doping of a first conductivity type;
a second channel portion of said channel region having a second doping of a second conductivity type that is inverse to said first conductivity type;
a continuous gate electrode structure having a first gate portion formed on said first channel portion and a second gate portion formed on said second channel portion, said first gate portion comprising a first gate dielectric material and a second gate dielectric material comprising a metal formed above said first gate dielectric material and said second gate portion comprising a third gate dielectric material of different material than said first gate dielectric material, a layer of said first gate dielectric material formed above said third gate dielectric material, and a layer of said second gate dielectric material formed above said layer of said first gate dielectric material;
a drain region formed so as to connect to said second channel portion; and
a source region formed so as to connect to said first channel portion.

2. The semiconductor device of claim 1, further comprising a buried insulating layer formed below said channel region and said drain and source regions.

3. The semiconductor device of claim 1, wherein a length of said second channel portion is greater than a length of said first channel portion.

4. The semiconductor device of claim 3, wherein said second channel portion is formed as a fully depleted semiconductor region.

5. The semiconductor device of claim 3, wherein a first thickness of said first gate dielectric material is less than a second thickness of said third gate dielectric material of said second gate portion.

6. The semiconductor device of claim 5, wherein said first gate dielectric material comprises a high-k dielectric material.

7. The semiconductor device of claim 2, further comprising a doped well region formed below said buried insulating layer, wherein said doped well region is connected to a control voltage source.

8. The semiconductor device of claim 1, further comprising a low-voltage field effect transistor that comprises a second channel region having a first thickness that is equivalent to a second thickness of said first and second channel portions.

9. The semiconductor device of claim 8, wherein said low-voltage field effect transistor is a fully depleted SOI transistor having a gate electrode structure with a gate length of 30 nm or less.

10. A method, comprising:
forming a channel region of a field effect transistor of a semiconductor device in a semiconductor layer, said channel region having a first channel portion doped with a dopant species of a first conductivity type and a second channel portion doped with a dopant species of a second conductivity type; and
forming a gate electrode structure on said channel region, said gate electrode structure having a first gate portion formed on said first channel portion and a second gate portion formed on said second channel portion, said first gate portion comprising a first gate dielectric material and a second gate dielectric material comprising a metal formed above said first gate dielectric material, and said second gate portion comprising a third gate dielectric material of different material than said first gate dielectric material, a layer of said first gate dielectric material formed above said third gate dielectric material, and a layer of said second gate dielectric material formed above said layer of said first gate dielectric material.

11. The method of claim 10, wherein forming said gate electrode structure comprises forming said first gate dielectric material with a first thickness on said first channel portion and forming said third gate dielectric material with a second thickness greater than said first thickness on said second channel portion.

12. The method of claim 10, wherein forming said gate electrode structure comprises forming a first layer of said third gate dielectric material above said first and second channel portions, removing a portion of said first layer of said third gate dielectric material from above said first channel portion and forming said layers of said first gate dielectric material and said second gate dielectric material above said first and second channel portions, said layer of said first gate dielectric material directly contacting an upper surface of a remaining portion of said first layer of said second gate dielectric material, said first gate dielectric material comprising a high-k dielectric material.

13. The method of claim 10, wherein forming said channel region comprises introducing said first dopant species into said first channel portion and concurrently into a well region of a first low-voltage field effect transistor of said second conductivity type.

14. The method of claim 13, wherein forming said channel region further comprises introducing said second dopant species into said second channel portion and concurrently into a well region of a second low-voltage field effect transistor of said first conductivity type.

15. The method of claim 10, further comprising forming drain and source regions laterally adjacent to said gate electrode structure by epitaxial growth.

16. The method of claim 10, further comprising providing a buried insulating layer prior to forming said channel region.

17. The method of claim 16, wherein said buried insulating layer is provided with a thickness of 50 nm or less.

18. A method of forming a field effect transistor, said method comprising:
introducing a first dopant species into a first portion of a semiconductor layer of a semiconductor device so as to form a first channel portion, said semiconductor layer being formed on a buried insulating layer;
introducing a second dopant species into a second portion of said semiconductor layer so as to form a second channel portion, said first and second dopant species inducing different conductivity types in said first and second channel portions, respectively;
forming a gate electrode structure above said semiconductor layer so as to form a first gate portion on said first channel portion and a second gate portion on said second channel portion, said first gate portion comprising a first gate dielectric material and a second gate dielectric material comprising a metal formed above said first gate dielectric material, and second gate portion comprising a third gate dielectric material of different material than said first gate dielectric material; and
forming drain and source regions laterally adjacent to said gate electrode structure.

19. The method of claim 18, wherein forming said gate electrode structure comprises forming said first gate dielectric material with a first thickness and forming said third gate dielectric material with a second thickness greater than said first thickness on said second channel portion.

20. The method of claim 19, wherein said second channel portion has a first length greater than a second length of said first channel portion.
